(19) United States
(12) Patent Application Publication
(10) Pub. No.: US 2011/0233573 A1
(43) Pub. Date: Sep. 29, 2011

(54) Method for Producing Temperature-Stable Large-Size Emitting LEDs and LEDs

(75) Inventors: Alexander Eychmüller, Dresden (DE); Nikolai Gaponik, Dresden (DE); Tobias Otto, Dresden (DE); Paul Mundra, Schland/Spree (DE); Elena Frolova, Minsk (BY)

(73) Assignee: TECHNISCHE UNIVERSITAET DRESDEN, Dresden (DE)

(21) Appl. No.: 13/133,387

(22) PCT Filed: Dec. 9, 2009
(86) PCT No.: PCT/EP2009/066719

§ 371 Date: Jun. 8, 2011

(30) Foreign Application Priority Data
Dec. 10, 2008 (DE) 10 2008 062 283.4

(51) Int. Cl. H01L 33/02; B82Y 99/00

(52) U.S. Cl. 257/88; 438/34; 257/103; 438/46; 977/773; 257/E33.013

(57) ABSTRACT

The invention relates to a method for producing temperature-stable large-size emitting LEDs and LEDs produced by said method. The method is characterised in that a large-area emitting light emitter is provided in the form of semiconductor nanocrystals which furthermore is temperature-stable and has a narrow band emission. A colloidal solution of emitting nanocrystals and a matrix of either inorganic gels or at least one polymer are alternately applied to the substrate with the first electrode by spraying, as a result of the electrostatic interactions between substrate, nanoparticles and inorganic gels or polymers, the nanopartides or the polymers of the matrix are adsorbed and the impurities run down with the solvent. The layer of alternately sprayed nanocrystals and matrix are heated to give a gel cross-linking the metal oxide nanoparticles, wherein thee size of thee semiconductor nanocrystals which determine the emission wavelength are determined by the temperature and duration of the heating. The second electrode is then applied by means of a conventional PVD method.

The invention concerns methods for producing temperature-stable light emitting diodes emitting across a large area, comprising a light-emitting transparent substrate, a transparent first electrode, and a second electrode; light emitting diodes produced thereby; and uses of solutions of emitting nanocrystals and solutions of a matrix.

Known methods for producing light emitting diodes are based on epitaxy methods with an ordered crystal growth on a support layer.

The starting point for the manufacture of luminescence diodes is a monocrystalline base material that, because of the high manufacturing temperatures, contains contaminants and a plurality of crystal defects. Crystal defects cause non-emitting recombinations so that the efficiency is very low. The monocrystals are used as a substrate that provides support and predetermines the crystal orientation. On it, the differently doped layers applied by epitaxy methods and having the required luminescence properties will grow. After producing the pn junctions and contacts, the luminescence diodes are individualized, applied to a conductor, contacted and enveloped. This envelope serves for protection of the luminescence diode, determines its emitting characteristic, and improves the light emitting conditions.

Moreover, light emitting diodes with semiconductor nanocrystals (NLEDs) are known also. Colloidal semiconductor nanoparticles are luminophores that are suitable for development of a new generation of electroluminescence units. NLEDs have several advantages, for example, spectral-pure emission colors.

In this connection, the nanocrystals absorb in a very broad wavelength range, but emit within a very narrow band. The luminescence can be excited photonically or electronically. In order to obtain an emitting component, nanoparticles are applied onto transparent substrates by spin coating or by slow immersion and withdrawal in colloidal solutions of the nanoparticles (dip coating) or by alternating multiple immersion in differently charged nanoparticles or polymer ions (so-called layer-by-layer method).

Moreover, the publication WO 2008/030474 A2 “Automated layer by layer technology” discloses a method for spraydeposition of polymer cations and polymer anions for producing uniform thin film deposits in the nanometer range on a substrate.

A disadvantage is that light emitting diodes that emit across a large surface area can be produced only by application of conducting polymers or organic dyes that, however, are thermally not stable and have broad emission bands.

The invention disclosed in claims 1, 16, and 17 has the object to provide a light emitting diode emitting across a large surface area on the basis of semiconductor nanocrystals that is thermally stable and has a narrow-band emission.

This object is solved by the features disclosed in claims 1, 16, and 17.

The methods for producing temperature-stable light emitting diodes that emit across a large surface area, comprising a transparent light-emitting substrate, a transparent first electrode, and a second electrode, are characterized in particular in that a light emitting diode emitting across a large surface area is provided on the basis of semiconductor nanocrystals, that is moreover thermally stable and that has a narrow-band emission.

For this purpose, a colloidal solution of emitting nanocrystals and a matrix of either inorganic gels or at least one polymer are sprayed alternatingly onto the substrate with the first electrode, wherein, as a result of the electrostatic interactions between substrate, nanoparticles and inorganic gels or polymers, the nanoparticles or polymers of the matrix are adsorbed and the contaminants drain with the solvent downwardly and therefore are no longer participating in the layer formation. The layer of alternatingly sprayed-on nanocrystals and the matrix as gel is subsequently heated for gel crosslinking of the metal oxide nanoparticles and release of water wherein the parameter that determines the emission wavelength of the semiconductor nanocrystals is determined by the temperature and duration of heating. Subsequently, the second electrode is applied by means of a known PVD method. In this connection, PVD refers to physical vapor deposition. These are known vapor depositing methods in evacuated processing chambers.

Accordingly, for the light emitting diode a layer comprised of monolayers is formed between the first electrode and the second electrode wherein each of the monolayers is formed of a sprayed-on colloidal solution of emitting nanocrystals and of a sprayed-on matrix. In this connection, the matrix is either metal oxide nanocrystals in the form of gels or is a polymer.

Advantageously, for realizing the light emitting diodes emitting across a large surface area the colloidal solutions or polymers are alternatingly sprayed onto the substrate. When doing so, a self-cleaning of each individual layer during its realization will occur; this is a great advantage in comparison to the immersion process. While the sprayed-on solutions drain downwardly, as a result of the electrostatic interactions between substrate, nanoparticles, and metal oxides or polymers, the nanoparticles or polymers of the matrix are adsorbed. The contaminants however drain together with the solvent downwardly and are no longer participating in the layer formation. This leads to very homogenous and clean layers. Accordingly, significantly fewer contaminants are present that otherwise will lead to non-emitting recombinations. Accordingly, the efficiency of the light emitting diodes is improved.

For the light emitting diodes advantageously semiconductor nanocrystals of any size can be employed wherein the size determines the emission wavelength. Accordingly, different emission wavelengths in the visible, ultraviolet and infrared wavelength range can be realized. The size of the semiconductor nanocrystals can be determined by variation of the synthesis parameters.

Advantageously, moreover light emitting diodes with very narrow emission bands can be produced.

Accordingly, light emitting diodes that emit across a large surface area can be provided wherein the size is determined by the appropriate selection of the size of the spray cone.

The light emitting diodes produced with inorganic gels and semiconductor nanocrystals are characterized moreover by high thermal stability up to 200° C. Advantageously, by use of inorganic gels, the substrates of the light emitting diodes have at high temperatures a high mechanical stability in contrast to those with organic polymers.

For producing the light emitting diodes advantageously a device is used therefor wherein a first atomizer either with a colloidal solution with a matrix or a polymer solution and a second atomizer with a colloidal solution with negatively charged nanocrystals that, by heating to 100° C. after spraying, are converted into glass-hard gels as well as a third atomizer with water are arranged in the form of an atomizer station opposite the substrate with the first electrode such that the base surface of the spray cone is greater than that of the substrate with the first electrode. Moreover, the substrate with the first electrode is arranged at an angle relative to the horizontal. Moreover, the atomizer station is coupled with a device for performing a PVD method for application of the second electrode. Coupling is based in this connection on a known transport device for substrate.

In this way, in a simple and economical way large surface area light emitting diodes can be provided.

Advantageous embodiments of the invention are disclosed in claims 2 to 15.

Beneficial nanocrystals according to the embodiment of claim 2 are
II-IV semiconductor nanocrystals in the form of CdTe, CdSe, CdS, ZnSe, ZnSeTe, HgTe, HgCdTe, ZnO, ZnS, ZnTe, Hg₁₋ₓCdₓTe, BeSe, BeTe, HgS;
III-V semiconductor nanocrystals in the form of GaP, GaAs, InP, InSb, InAs, GaSb, GaN, AIN, InN, AlₓGa₁₋ₓAs,
III-VI semiconductor nanocrystals in the form of GaS, GaSe, GaTe, InS, InSe, InTe,
I-III-VI semiconductor nanocrystals in the form of CuInSe₂, CuInGaSe₂, CuInS₂, CuInGaS₂, or
core-shell partides in the form of CdSe/CdS, CdS/ZnS, ZnSe/CdS, ZnSe/ZnS, HgTe, CdS or
elongate core-shell particles of CdSe/CdS with a spherical CdSe core and an elongate CdS shell.

The CdTe semiconductor nanocrystals according to the embodiment of claim 3 are advantageously CdTe semiconductor nanocrystals that are produced by aqueous synthesis of a mixture of Cd(ClO₄)₂ and mercapto propionic acid, as a stabilizer for slowing crystal growth as well as for determining the charge, with introduction of hydrogen telluride at room temperature and in inert gas atmosphere as well as subsequent heating, filtering, concentrating, precipitating with isopropanol, and dissolving in water.

The elongate CdSe/CdS core-shell nanoparticles according to the embodiment of claim 4 are produced by two-step synthesis according to the hot injection method, wherein
a mixture of trioctyl ph osphine oxide, octadecyl phosphorous acid and cadmium oxide are heated under inert gas and trioctyl phospine selenide is added at 300° C. and subsequently, after cooling, trioctyl phosphine sulfide trioctyl phosphine is added,
the obtained CdSe cores together with trioctyl phospine oxide are injected into a 350° C. hot mixture of with trioctyl phosphine oxide, octadecyl phosphorous acid, hexyl phosphorous acid, and trioctyl phosphine,
the particles, dissolved prior to this in toluene, are precipitated with methanol, centrifuged, and dispersed with hexane and then a solution of potassium hydroxide and mercapto propionic acid in methanol is added and shaken, and
the methanol phase is separated, centrifuged, and the precipitation is dissolved in potassium hydroxide solution.

The colloidal solution for spray deposition according to the embodiment of claim 5 is a solution comprised of CdTe semiconductor nanocrystals and water, advantageously ultrapure water.

The molar ratio of Cd:mercapto propionic acid:Te according to the embodiment of claim 6 is advantageously 2:2.6:1.

Beneficially, the colloidal solution forspray deposition according to the embodiment of claim 7 is a solution comprised of elongate CdSe/CdS core-shell particles and water.

The matrix according to the embodiment of claim 8 is comprised advantageously of an Al₂O₃ gel, ZnO gel, SnO gel, TiO₂ gel or ZrO₂ gel.

The aluminum oxide gel is advantageously an aluminum oxide gel that is prepared by the sol-gel method. In this method, an ammonia solution is dripped into a solution of Al(NO₃)₃*9H₂O and HNO₃. This reaction solution is then centrifuged and the supernatant solution is removed and water is added and is again centrifuged until the self-peptization point is reached. The gel after peptization is converted by ultrasound into the sol. The gels that are produced by aging are stabilized by addition of thioglycolic acid. By addition of nitric acid, a positive charge of the aluminum oxide nanoparticles is achieved.

The titanium dioxide gel is advantageously a titanium dioxide gel produced by sol-gel method. In this method, titanium tetrachloride is dripped into water. To this reaction solution potassium hydroxide solution is dripped and the obtained gel is dialyzed with water until a pH value of 3 is adjusted.

The inorganic gels are advantageously thermally stable up to 200° C., are water-soluble, and highly transparent.

The matrix is comprised according to the embodiment of claim 9 of a polymer of a sprayed-on polymer solution.

The sprayed-on polymer solution according to the embodiment of claim 10 is advantageously a polymer solution of poly(diallyldimethylammonium chloride) (PDDA) wherein the poly(diallyldimethylammonium ion) is positively charged.

The spray solutions for the sprayed colloidal solution and the sprayed matrix contain according to the embodiment of claim 11 surface active agents so that the surface tension is reduced and the sprayed droplet size as well as the sprayed droplet speed are optimized.

The spray solutions for the sprayed colloidal solution and the sprayed matrix contain according to the embodiment of claim 12 polymers so that the viscosity is increased and the sprayed droplet size as well as the sprayed droplet speed are optimized.

According to the embodiment of claim 13, the light emitting diode has at least one electron and hole transport layer.

Each of the atomizers according to the embodiment of claim 14 is connected to a nitrogen source so that by means of the nitrogen flow that passes a nozzle the solution that exits therefrom, respectively, is entrained in the form of very small droplets. In this way, the solution can be applied in a simple way onto the substrate with the electrode.

According to the embodiment of claim 15, by applying an electrical field the transparent first electrode is electrically positively charged relative to the spray solutions and their droplets.

In this way, the sprayed mist is directed in a targeted fashion onto the substrate and losses are avoided.

One embodiment of the invention is illustrated in the drawings in a basic illustration and will be explained in the following in more detail.

It is shown in:

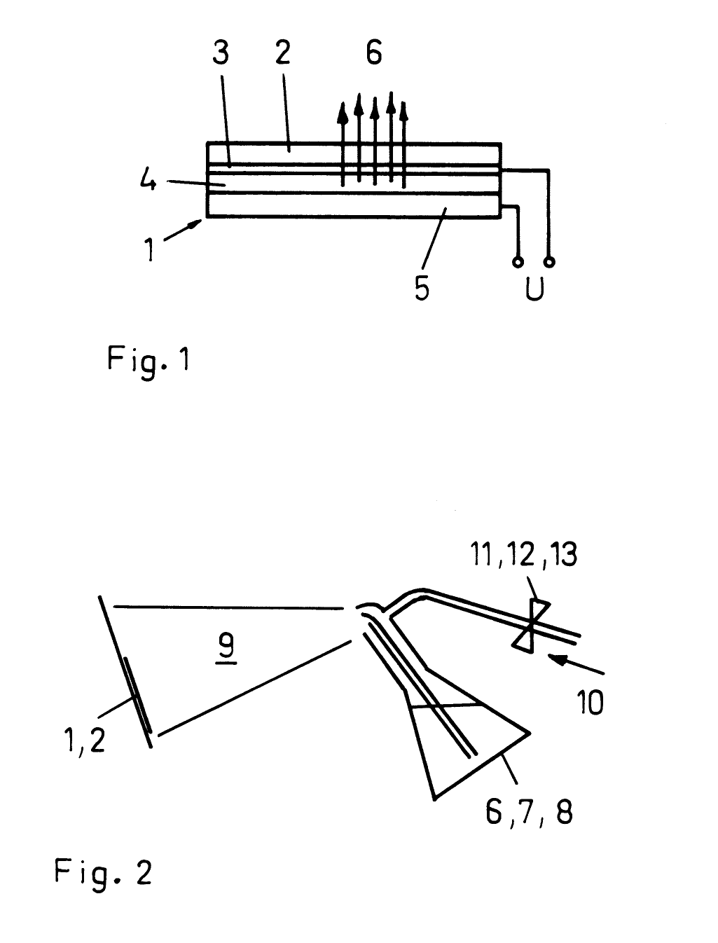

FIG. 1 a light emitting diode;

FIG. 2 a device for producing light emitting diodes in a side view, and

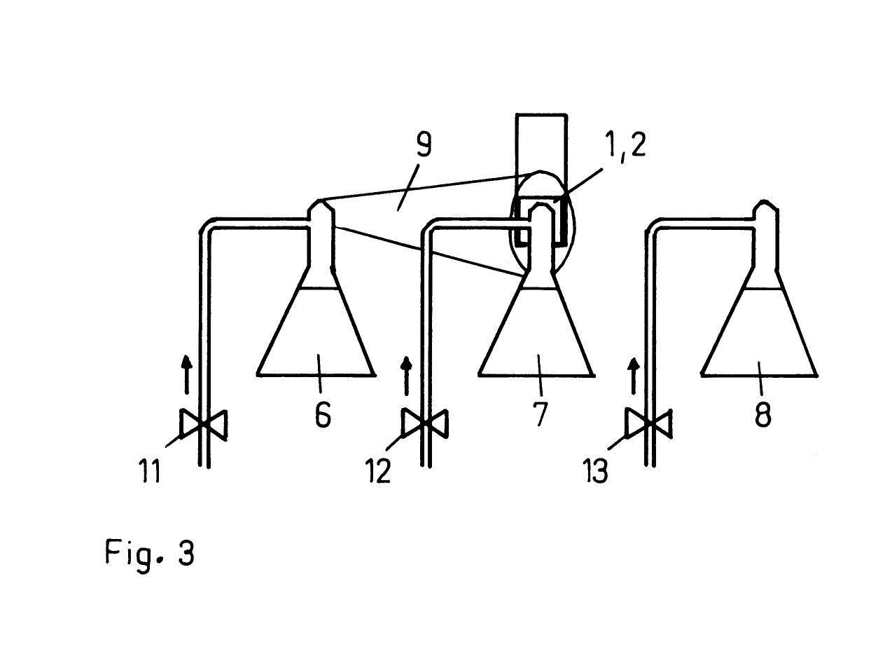

FIG. 3 the device in a front view.

In a method for producing temperature-stable light emitting diodes emitting across a large surface area, comprising a transparent layer, a transparent first electrode, and a second electrode, a colloidal solution of emitting nanocrystals and a matrix either of inorganic gels or at least one polymer are sprayed alternatingly onto the substrate with the first electrode, wherein, as a result of the electrostatic interactions between substrate, nanoparticles, and inorganic gels or polymers, the nanoparticles or polymers of the matrix are adsorbed and the contaminants will drain downwardly with the solvent and therefore no longer participate in the layer formation.

The layer of the alternatingly sprayed-on nanocrystals and the matrix in the form of the gel is heated for gel crosslinking of the metal oxide nanoparticles and release of water, wherein the parameter that determines the emission wavelength of the semiconductor nanocrystals is determined by the temperature and duration of heating.

The second electrode is applied by means of a known PVD method. This is done by means of vapor deposition of a layer as an electrode.

In this connection, the light emitting diode 1 is comprised substantially of a transparent light emitting substrate 2 with a transparent first electrode 3, a second electrode 5, and a layer 4, formed of emitting nanocrystals and a matrix, between the electrodes.

FIG. 1 shows a light emitting diode in a basic illustration.

In the following, first the aqueous synthesis of cadmium telluride nanocrystals (CdTe nanocrystals) is described.

The manufacture of other semiconductor nanocrystals such as
II-IV semiconductor nanocrystals in the form of CdTe, CdSe, CdS,

ZnSe, ZnSeTe, HgTe, HgCdTe, ZnO, ZnS, ZnTe, Hg₁₋ₓCdₓTe, BeSe, BeTe, HgS;
III-V semiconductor nanocrystals in the form of GaP, GaAs, InP, InSb, InAs, GaSb, GaN, AIN, InN, AlₓGa₁₋ₓAs,
III-VI semiconductor nanocrystals in the form of GaS, GaSe, GaTe, InS, InSe, InTe,
I-III-VI semiconductor nanocrystals in the form of CuInSe₂, CuInGaSe₂, CuInS₂, CuInGaS₂,
   or similar ones is also possible thereby. Semiconductor nanocrystals can be obtained also in organic solvents.

For slowing the crystal growth during the synthesis of the semiconductor nanoparticles a stabilizer (mercapto propionic acid) is added that also determines the charge of the nanocrystals.

Into a mixture of Cd(ClO₄)2 and mercapto propionic acid in water, adjusted to pH 12 by means of a 1 molar sodium hydroxide solution, hydrogen telluride is introduced at room temperature and under argon atmosphere (molar ratio Cd:mercapto propionic acid:Te 2:2.6:1). The reaction solution is heated to boiling after the introduction. By sample removal of reaction solution during heating, the growth of the nanocrystals can be followed by fluorescence spectrometry. After 5 minutes, the nanocrystals have reached a size of approximately 2 nm and emit green.

The duration of heating controls the crystal growth and determines the emission wavelength. The colloidal CdTe solution is subsequently filtered, concentrated, and the nanoparticles are precipitated with isopropanol. The supernatant solution is discharged and the solid semiconductor nanocrystals are dissolved in water. This solution is used immediately for spray deposition.

The colloidal aluminum oxide as matrix was prepared by means of the sol-gel method. For this purpose, a mixture of Al(NO₃)₃*9H₂O and HNO₃ was added dropwise to an ammonia solution with stirring until the pH value dropped to 9. The reaction solution was subsequently centrifuged, the supernatant solution was removed, water was added and centrifugation repeated. This operation was repeated until the self-peptization point (pH=7+0.2). After peptization the gel was converted by ultrasound into the sol. The subsequent 24-hour aging of the particles leads to aggregates of a size of 245 nm. They are stabilized by adding thioglycolic acid. After additional 24 hours, nitric acid is added until pH 4 is reached in order to effect a positive charge of the aluminum oxide particles.

For deposition, three atomizers 6, 7, 8 are used whose spray nozzle has an inner diameter of 0.5 mm. They are arranged such that the cone axis of the spray cone 9 is slanted at an angle of 30° relative to the horizontal. The substrate 2 with the transparent first electrode 3 is positioned at a spacing of 12 cm away from the spray opening and is also slanted at 30° relative to the horizontal so that the spray cone axis is perpendicular to the substrate 2 with the transparent first electrode. The spray solutions are driven off by nitrogen 10 at a supply pressure of 0.5 bar. The indicated geometric and physical conditions are only exemplary.

The atomizers 6, 7, 8 are supplied by solenoid valves 11, 12, 13 with nitrogen 10. The solenoid valves 11, 12, 13 are connected for control to a data processing system.

FIG. 2 shows a device for producing light emitting diodes in a basic side view.

FIG. 3 shows the device in a basic front view.

The atomizer 6 contains a colloidal solution with positively charged aluminum oxide nanoparticles, the atomizer 7 a colloidal solution with negatively charged CdTe nanocrystals, and the atomizer 8 contains ultrapure water for cleaning the deposited layers. As a conducting and transparent substrate 2 indium tin oxide (ITO)-coated glass with an ITO layer thickness of 125 nm as a transparent first electrode 3 is used. The substrate 2 with the transparent first electrode 3 is degreased with acetone before spray deposition and then cleaned with ultrapure water.

Sequentially, aluminum oxide nanoparticles, water, CdTe nanocrystals and then again water are sprayed on. In this way, on the glass substrate a double layer of aluminum oxide nanoparticles and CdTe nanoparticles is formed. The spraying process is repeated until, for example, 30 double layers as layer 4 are produced. In Table 1 exemplary spraying parameters are compiled. A spraying cycle lasts 10 minutes and is repeated 30 times.

TABLE 1

| spraying time/s | spraying process | atomizer |
|---|---|---|
| 3 | Al₂O₃ | 1 |
| 54 | intermission | |
| 1 | Al₂O₃ | 1 |
| 59 | intermission | |
| 5 | water | 3 |
| 56 | intermission | |
| 4 | CdTe | 2 |
| 55 | intermission | |
| 1 | CdTe | 2 |
| 59 | intermission | |
| 5 | water | 3 |
| 56 | intermission | |

In Table 2 the physicochemical parameters of the employed materials are listed.

TABLE 2

| | | | | | poly(diallyl- | |
|---|---|---|---|---|---|---|
| | | | | | dimethyl- | |
| | cadmium | | aluminum | | ammonium | ultrapure |
| reagent | telluride | | oxide | | chloride) | water |
| concentration | 2.9 * | | 0.01 | mol/l | 3.1 * | |
| | 10⁻⁵ mol/l | | | | 10⁻² mol/1 | |
| particle size | 2.8 | nm | 245 | nm | | |
| emission | 627 | nm | none | | none | |
| wavelength | | | | | | |
| pH value | 10 | | 4 | | | 7 |
| zeta potential | −65 | mV | +54 | mV | | |

| conductivity | | | | | 18 |
|---|---|---|---|---|---|
| solvent | NaCl solution | | diluted nitric | NaCl solution | |
| | 0.1 | mol/l | acid | 0.1 mol/1 | |

In one embodiment instead of the matrix with aluminum nanoparticles a matrix of polymer solutions of poly(diallyldimethylammonium chloride) (PDDA) can be used. The poly(diallyldimethylammonium ion) is positively charged. In Table 3 exemplary parameters are compiled.

TABLE 3

| spraying time/s | spraying process | atomizer |
|---|---|---|
| 3 | PDDA | 1 |
| 54 | intermission | |
| 1 | PDDA | 1 |
| 59 | intermission | |
| 5 | water | 3 |
| 56 | intermission | |
| 4 | CdTe | 2 |
| 55 | intermission | |
| 1 | CdTe | 2 |
| 59 | intermission | |
| 5 | water | 3 |
| 56 | intermission | |

The aluminum oxide/nanocrystal layers are dried at 100° C. for 1 h in order to effect crosslinking of the aluminum oxide particles.

The polymer/nanocrystal layers are dried for 3 h in vacuum at room temperature.

After this layer deposition, the second electrode 5 is vapor-deposited in the form of aluminum.

The light emitting diode 1 is comprised of a transparent substrate 2 of glass that is coated with indium tin oxide (ITO, 125 nm thick, unpolished surface) as a transparent first electrode 3. It has a conductivity of 13 ohm/cm². Following it are 30 double layers of crosslinked aluminum oxide nanoparticles or PDDA and CdTe nanocrystals. The CdTe nanocrystal layer (A) adjoins the ITO layer that is the first electrode 3. It is followed by an aluminum oxide layer (B) or a PDDA layer as mentioned above. The second electrode 5 of aluminum ad joins the last double layer of the layer 4.

The layer sequence is: glass-ITO-(A-B)30-Al. The 30 double layers have a layer thickness of 90 nm.

The forward bias of the light emitting diode is 3.0 V; the current density is 16 mA/cm².

In embodiments solutions of emitting nanocrystals comprised of elongate CdSe/CdS core-shell nanocrystals are used. The CdSe core determines mainly the emission wavelength and the CdS shell ensures photo stability and minimal reabsorption of light in thick layers.

In further embodiments solutions of infrared-emitting nanocrystals comprised of HgTe, PbS, PbSe, CdHgTe and core-shell particles of HgTe/CdS are used for producing light emitting diodes.

In a further embodiments solutions of ultraviolet-emitting nanoparticles such as ZnSe are used for producing light emitting diodes.

1. Method for producing temperature-stable light emitting diodes emitting across a large surface area, comprising a transparent substrate, a transparent first electrode, and a second electrode, characterized in that a colloidal solution of emitting nanocrystals and a matrix of either inorganic gels or at least one polymer are sprayed alternatingly onto the substrate with the first electrode, wherein, as a result of the electrostatic interactions between substrate, nanoparticles, and inorganic gels or polymers, the nanoparticles or polymers of the matrix are adsorbed and the contaminants will drain downwardly with the solvent and therefore do not participate in the layerformation, in that the layer of the alternatingly sprayed-on nanocrystals and the matrix as gel is heated for gel crosslinking of the metal oxide nanoparticles and release of water, wherein the parameter that determines the emission wavelength of the semiconductor nanocrystals is determined by the temperature and the duration of heating, and in that the second electrode is applied by means of a PVD method.

2. Method according to claim 1, characterized in that the nanocrystals are
II-IV semiconductor nanocrystals in the form of CdTe, CdSe, CdS, ZnSe, ZnSeTe, HgTe, HgCdTe, ZnO, ZnS, ZnTe, Hg_{1 -x}CdₓTe, BeSe, BeTe, HgS;
III-V semiconductor nanocrystals in the form of GaP, GaAs, InP, InSb, InAs, GaSb, GaN, AIN, InN, AlₓGa₁₋ₓAs,
III-VI semiconductor nanocrystals in the form of GaS, GaSe, GaTe, InS, InSe, InTe,
I-III-VI semiconductor nanocrystals in the form of CuInSe₂, CuInGaSe₂, CuInS₂, CuInGaS₂,
or that the nanoparticles are core-shell particles in the form of CdSe/CdS, CdS/ZnS, ZnSe/CdS, ZnSe/ZnS, HgTe, CdS,
or that the nanoparticles are elongate core-shell particles of CdSe/CdS with a spherical CdSe core and an elongate CdS shell.

3. Method according to claim 2, characterized in that the CdTe semiconductor nanoparticles are CdTe semiconductor nanoparticles prepared by an aqueous synthesis of a solution of Cd(ClO₄)₂ and mercapto propionic acid, as a stabilizer for slowing the crystal growth as well as for determining the charge, with introduction of hydrogen telluride at room temperature and in an inert gas atmosphere as well as subsequent heating, filtering, concentrating, precipitating with isopropanol, and dispersing in water.

4. Method according to claim 2, characterized in that the elongates CdSe/CdS core-shell nanoparticles are produced by two-step synthesis according to the hot injection method, wherein a mixture of trioctyl ph osphine oxide, octadecyl phosphorous acid and cadmium oxide is heated under inert gas and trioctyl phospine selenide is added at 300° C. and subsequently, after cooling, trioctyl phosphine sulfide trioctyl phosphine is added; the obtained CdSe cores together with trioctyl phospine oxide are injected into a 350° C. hot mixture of with trioctyl phosphine oxide, octadecyl phosphorous acid, hexyl phosphorous acid, and trioctyl phosphine; the particles, dissolved prior to this in toluene, are precipitated with methanol, centrifuged, and dispersed with hexane and then a solution of potassium hydroxide and mercapto propionic acid in methanol is added and shaken; and the methanol phase is separated, centrifuged, and the precipitation is dissolved in potassium hydroxide solution.

5. Method according to claim 3, characterized in that the colloidal solution for spray deposition is a solution comprised of CdTe semiconductor nanocrystals and water.

6. Method according to claim 3, characterized in that the molar ratio of Cd:mercapto propionic acid:Te is 2:2.6:1.

7. Method according to claim 3, characterized in that the colloidal solution for spray deposition is a solution comprised of elongate CdSe/CdS core shell particles and water.

8. Method according to claim 1, characterized in that the inorganic gels are Al₂O₃ gels, ZnO gels, SnO gels, TiO₂ gels, or ZrO₂ gels.

9. Method according to claim 1, characterized in that the matrix is comprised of a polymer of a sprayed-on polymer solution.

10. Method according to claim 9, characterized in that the sprayed-on polymer solution is a polymer solution of poly(diallyldimethylammonium chloride) (PDDA)wherein the poly(diallyldimethylammonium ion) is positively charged.

11. Method according to claim 1, characterized in that for reducing the surface tension and for optimizing the sprayed droplet size as well as the sprayed droplet speed the spray solutions for the sprayed colloidal solution and the sprayed matrix contain surface active agents.

12. Method according to claim 1, characterized in that for increasing the viscosity and for optimizing the sprayed droplet size as well as the sprayed droplet speed the spray solutions for the sprayed colloidal solution and the sprayed matrix contain polymers.

13. Method according to claim 1, characterized in that the light emitting diode has at least one electron and hole transport layer.

14. Method according to claim 1, characterized in that by means of a nitrogen flow that passes a nozzle of an atomizer the solution exiting therefrom, respectively, is atomized and is entrained in the form of very small droplets.

15. Method according to claim 1, characterized in that by applying an electrical field the transparent first electrode is electrically positively charged relative to the spray solutions and their droplets.

16. Light emitting diode with a transparent substrate, a transparent first electrode, and a second electrode, prepared by using the method according to claim 1, characterized in that between the first electrode (3) and the second electrode (5) a layer (4) of several double layers, each comprised of emitting nanocrystals based on a colloidal solution of emitting nanocrystals and a matrix either of inorganic gels or at least one polymer, is arranged so that layered monolayers of the nanocrystals and either the gels or the polymers are present.

17. Use of solutions of emitting nanocrystals and solutions of a matrix, characterized in that double layers each comprised of a sprayed colloidal solution of emitting nanocrystals and a sprayed matrix of either inorganic gels or at least one polymer are used for producing light emitting diodes (1) with a transparent substrate (2), a transparent first electrode (3), and a second electrode (5), wherein the size of semiconductor nanocrystals as emitting nanocrystals determine the emission wavelength.
